(19) United States
(12) Patent Application Publication
(10) Pub. No.: US 2026/0246524 A1
(43) Pub. Date: Aug. 20, 2026

(54) SEPARATE TRAINING APPROACH FOR CHANNEL STATE INFORMATION FEEDBACK

(71) Applicant: Nokia Technologies Oy, Espoo (FI)

(72) Inventors: Yihang HUANG, Shanghai (CN); Chen Hui YE, Shanghai (CN); Yijia FENG, Shanghai (CN)

(21) Appl. No.: 19/471,160

(22) PCT Filed: Apr. 6, 2023
(86) PCT No.: PCT/CN2023/086644

§ 371 Date: Sep. 30, 2025

(51) Int. Cl. H04B 7/06

(52) U.S. Cl. CPC H04B 7/0658; H04B 7/0626

(57) ABSTRACT

Embodiments of the present disclosure relate to devices, methods, apparatuses and computer readable storage media of separate training approach for CSI feedback. The method comprises receiving, at a terminal device and from a network device, a training dataset associated with CSI, a codebook of the network device and a first set of codeword indices associated with the codebook; and determining a CSI feedback compression of the terminal device based on a first codeword and a second codeword generated based on the training dataset, the codebook of the network device and the first set of codeword indices.

### FIELD

Embodiments of the present disclosure generally relate to the field of telecommunication and in particular to devices, methods, apparatuses and computer readable storage media of separate training approach for channel state information (CSI) feedback.

### BACKGROUND

The accurate feedback of CSI is extremely important for the efficient transmission of Frequency Division Duplexing (FDD) Multiple-Input Multiple-Output (MIMO), but the delivery of the original CSI to the base station consumes massive uplink resources. With the great success of AI-based feature extraction and image compression, the CSI feedback enhancement by using artificial intelligence (AI)/machine learning (ML) methods has been discussed and studied.

### SUMMARY

In general, example embodiments of the present disclosure provide a solution of separate training approach for CSI feedback.

In a first aspect, there is provided an apparatus. The apparatus comprises at least one processor; and at least one memory storing instructions that, when executed by the at least one processor, cause the apparatus at least to receive, from a network device, a training dataset associated with CSI, a codebook of the network device and a first set of codeword indices associated with the codebook; and determine a CSI feedback compression of the apparatus based on a first codeword and a second codeword generated based on the training dataset, the codebook of the network device and the first set of codeword indices.

In a second aspect, there is provided an apparatus. The apparatus comprises at least one processor; and at least one memory storing instructions that, when executed by the at least one processor, cause the apparatus at least to determine a latent vector based on a training dataset associated with CSI; determine a first set of codeword indices based on the latent vector and a codebook of the apparatus; and transmit, to a terminal device, the training dataset, the first set of codeword indices and the codebook.

In a third aspect, there is provide a method. The method comprises receiving, at a terminal device and from a network device, a training dataset associated with CSI, a codebook of the network device and a first set of codeword indices associated with the codebook; and determining a CSI feedback compression of the terminal device based on a first codeword and a second codeword generated based on the training dataset, the codebook of the network device and the first set of codeword indices.

In a fourth aspect, there is provide a method. The method comprises determining, at a network device, a latent vector based on a training dataset associated with CSI; determining, a first set of codeword indices based on the latent vector and a codebook of the network device; and transmitting, to a terminal device, the training dataset, the first set of codeword indices and the codebook.

In a fifth aspect, there is provided an apparatus comprising means for receiving, from a network device, a training dataset associated with CSI, a codebook of the network device and a first set of codeword indices associated with the codebook; and means for determining a CSI feedback compression of the apparatus based on a first codeword and a second codeword generated based on the training dataset, the codebook of the network device and the first set of codeword indices.

In a sixth aspect, there is provided an apparatus comprising means for determining a latent vector based on a training dataset associated with CSI; means for determining a first set of codeword indices based on the latent vector and a codebook of the apparatus; and means for transmitting, to a terminal device, the training dataset, the first set of codeword indices and the codebook.

In a seven aspect, there is provided a computer readable medium having a computer program stored thereon which, when executed by at least one processor of an apparatus, causes the apparatus to carry out the method according to the third aspect or the fourth aspect.

Other features and advantages of the embodiments of the present disclosure will also be apparent from the following description of specific embodiments when read in conjunction with the accompanying drawings, which illustrate, by way of example, the principles of embodiments of the disclosure.

### BRIEF DESCRIPTION OF THE DRAWINGS

Embodiments of the disclosure are presented in the sense of examples and their advantages are explained in greater detail below, with reference to the accompanying drawings.

FIG. 1 illustrates an example environment in which example embodiments of the present disclosure may be implemented;

FIG. 2 illustrates an example of an overall structure for CSI compression and reconstruction according to some example embodiments of the present disclosure;

FIG. 3 shows a signaling chart illustrating an example of process according to some example embodiments of the present disclosure;

FIG. 4 shows an example of a model for network device side training according to some example embodiments of the present disclosure;

FIG. 5 shows an example of a model for terminal device side training according to some example embodiments of the present disclosure;

FIG. 6 shows examples of training model for a simulation process according to some example embodiments of the present disclosure;

FIG. 7 show a convergence performance of simulation process according to some example embodiments of the present disclosure;

FIG. 8 shows a flowchart of an example method of separate training approach for CSI feedback according to some example embodiments of the present disclosure;

FIG. 9 shows a flowchart of an example method of separate training approach for CSI feedback according to some example embodiments of the present disclosure;

FIG. 10 shows a simplified block diagram of a device that is suitable for implementing example embodiments of the present disclosure; and

FIG. 11 shows a block diagram of an example computer readable medium in accordance with some embodiments of the present disclosure.

Throughout the drawings, the same or similar reference numerals may represent the same or similar element.

### DETAILED DESCRIPTION

Principle of the present disclosure will now be described with reference to some example embodiments. It is to be understood that these embodiments are described only for the purpose of illustration and help those skilled in the art to understand and implement the present disclosure, without suggesting any limitation as to the scope of the disclosure. Embodiments described herein may be implemented in various manners other than the ones described below.

In the following description and claims, unless defined otherwise, all technical and scientific terms used herein may have the same meaning as commonly understood by one of ordinary skills in the art to which this disclosure belongs.

References in the present disclosure to “one embodiment,” “an embodiment,” “an example embodiment,” and the like indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It shall be understood that although the terms “first,” “second” and the like may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the listed terms.

As used herein, “at least one of the following: <a list of two or more elements>” and “at least one of <a list of two or more elements>” and similar wording, where the list of two or more elements are joined by “and” or “or”, mean at least any one of the elements, or at least any two or more of the elements, or at least all the elements.

As used herein, unless stated explicitly, performing a step “in response to A” does not indicate that the step is performed immediately after “A” occurs and one or more intervening steps may be included.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components etc., but do not preclude the presence or addition of one or more other features, elements, components and/or combinations thereof.

As used in this application, the term “circuitry” may refer to one or more or all of the following:
(a) hardware-only circuit implementations (such as implementations in only analog and/or digital circuitry) and
(b) combinations of hardware circuits and software, such as (as applicable):
   (i) a combination of analog and/or digital hardware circuit(s) with software/firmware and
   (ii) any portions of hardware processor(s) with software (including digital signal processor(s)), software, and memory (ies) that work together to cause an apparatus, such as a mobile phone or server, to perform various functions) and
(c) hardware circuit(s) and or processor(s), such as a microprocessor(s) or a portion of a microprocessor(s), that requires software (e.g., firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

As used herein, the term “communication network” refers to a network following any suitable communication standards, such as New Radio (NR), Long Term Evolution (LTE), LTE-Advanced (LTE-A), Wideband Code Division Multiple Access (WCDMA), High-Speed Packet Access (HSPA), Narrow Band Internet of Things (NB-IoT), an Enhanced Machine type communication (eMTC) and so on. Furthermore, the communications between a terminal device and a network device in the communication network may be performed according to any suitable generation communication protocols, including, but not limited to, the first generation (1G), the second generation (2G), 2.5G, 2.75G, the third generation (3G), the fourth generation (4G), 4.5G, the fifth generation (5G) communication protocols, and/or any other protocols either currently known or to be developed in the future. Embodiments of the present disclosure may be applied in various communication systems. Given the rapid development in communications, there will of course also be future type communication technologies and systems with which the present disclosure may be embodied. It should not be seen as limiting the scope of the present disclosure to only the aforementioned system.

As used herein, the terms “network device”, “radio network device” and/or “radio access network device” refers to a node in a communication network via which a terminal device accesses the network and receives services therefrom. The network device may refer to a base station (BS) or an access point (AP), for example, a node B (NodeB or NB), an evolved NodeB (eNodeB or eNB), an NR NB (also referred to as a gNB), a Remote Radio Unit (RRU), a radio header (RH), a remote radio head (RRH), a relay, an Integrated Access and Backhaul (IAB) node, a low power node such as a femto, a pico, a non-terrestrial network (NTN) or non-ground network device such as a satellite network device, a low earth orbit (LEO) satellite and a geosynchronous earth orbit (GEO) satellite, an aircraft network device, and so forth, depending on the applied terminology and technology. In some example embodiments, low earth orbit (RAN) split architecture includes a Centralized Unit (CU) and a Distributed Unit (DU). In some other example embodiments, part of the radio access network device or full of the radio access network device may embarked on an airborne or space-borne NTN vehicle.

The term “terminal device” refers to any end device that may be capable of wireless communication. By way of example rather than limitation, a terminal device may also be referred to as a communication device, user equipment (UE), a Subscriber Station (SS), a Portable Subscriber Station, a Mobile Station (MS), or an Access Terminal (AT). The terminal device may include, but not limited to, a mobile phone, a cellular phone, a smart phone, voice over IP (VOIP) phones, wireless local loop phones, a tablet, a wearable terminal device, a personal digital assistant (PDA), portable computers, desktop computer, image capture terminal devices such as digital cameras, gaming terminal devices, music storage and playback appliances, vehicle-mounted wireless terminal devices, wireless endpoints, mobile stations, laptop-embedded equipment (LEE), laptop-mounted equipment (LME), USB dongles, smart devices, wireless customer-premises equipment (CPE), an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. The terminal device may also correspond to a Mobile Termination (MT) part of an IAB node (e.g., a relay node). In the following description, the terms “terminal device”, “communication device”, “terminal”, “user equipment” and “UE” may be used interchangeably.

As used herein, the term “resource,” “transmission resource,” “resource block,” “physical resource block” (PRB), “uplink resource,” or “downlink resource” may refer to any resource for performing a communication, for example, a communication between a terminal device and a network device, such as a resource in time domain, a resource in frequency domain, a resource in space domain, a resource in code domain, or any other resource enabling a communication, and the like. In the following, unless explicitly stated, a resource in both frequency domain and time domain will be used as an example of a transmission resource for describing some example embodiments of the present disclosure. It is noted that example embodiments of the present disclosure are equally applicable to other resources in other domains.

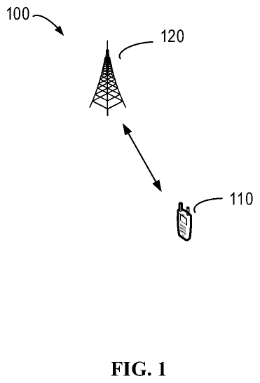

FIG. 1 shows an example communication network 100 in which embodiments of the present disclosure may be implemented. As shown in FIG. 1, the communication network 100 may include a terminal device 110. Hereinafter the terminal device 110 may also be referred to as a UE.

The communication network 100 may further include a network device 120. Hereinafter the network device 120 may also be referred to as a gNB or an eNB, respectively. The terminal device 110 may communicate with the network device 120 within a coverage of a cell 102 managed by the network device 120.

It is to be understood that the number of network devices and terminal devices shown in FIG. 1 is given for the purpose of illustration without suggesting any limitations. The communication network 100 may include any suitable number of network devices and terminal devices.

In some example embodiments, links from the network device 120 to the terminal device 110 may be referred to as a downlink (DL), while links from the terminal device 110 to the network device 120 may be referred to as an uplink (UL). In DL, the network device 120 is a transmitting (TX) device (or a transmitter) and the terminal device 110 is a receiving (RX) device (or receiver). In UL, the terminal device 110 is a TX device (or transmitter) and the network device 120 is a RX device (or a receiver).

Communications in the communication environment 100 may be implemented according to any proper communication protocol(s), includes, but not limited to, cellular communication protocols of the first generation (1G), the second generation (2G), the third generation (3G), the fourth generation (4G), the fifth generation (5G), the sixth generation (6G), and the like, wireless local network communication protocols such as Institute for Electrical and Electronics Engineers (IEEE) 802.11 and the like, and/or any other protocols currently known or to be developed in the future. Moreover, the communication may utilize any proper wireless communication technology, includes but not limited to: Code Division Multiple Access (CDMA), Frequency Division Multiple Access (FDMA), Time Division Multiple Access (TDMA), Frequency Division Duplex (FDD), Time Division Duplex (TDD), Multiple-Input Multiple-Output (MIMO), Orthogonal Frequency Division Multiple (OFDM), Discrete Fourier Transform spread OFDM (DFT-s-OFDM) and/or any other technologies currently known or to be developed in the future.

As described above, the CSI feedback enhancement by using AI/ML methods has been discussed and studied. To this aim, the 3rd Generation Partnership Project (3GPP) has approved a new study item (SI) in Release 18 to explore the benefits of augmenting the CSI feedback by AI/ML techniques.

The AI/ML study item use cases may focus on CSI feedback enhancement, e.g., overhead reduction, improved accuracy, prediction; Beam management, e.g., beam prediction in time, and/or spatial domain for overhead and latency reduction, beam selection accuracy improvement; and positioning accuracy enhancements for different scenarios including, e.g., those with heavy non-line of sight (NLOS) conditions.

Under the AI-based CSI feedback framework, the optimization of quantizer is categorized into two types in 3GPP Release 18, namely the quantization-unaware training, and the quantization-aware training. Under the quantization-unaware training framework, the quantizer formulation is not involved into the training process, which may introduce end-to-end performance degradation on account of the misalignment between the encoder/decoder and quantizer. In contrast, the quantization-aware training integrates the quantizer formulation into the encoder-decoder training to achieve a superior overall Key Performance Indicator (KPI) with all modules well aligned.

It has been agreed that two-sided model use case may be used in CSI compression and evaluate and study quantization of CSI feedback based on quantization non-aware training, quantization-aware training, quantization methods including uniform vs non-uniform quantization, scalar versus vector quantization, and associated parameters, e.g., quantization resolution, etc and How to use the quantization methods.

Regarding the training framework, 3GPP has defined three types of training frameworks, namely type 1, type 2, and type 3. The type 1 and type 2 training rely on the end-to-end gradient propagation from the decoder back to the encoder to simultaneously update the encoder and decoder, while the type 3 training assumes the UE-side training for encoder and NW-side training for decoder completed in a separate training session, so the NW-side decoder training would not require the detailed model parameters of the UE encoder for its own training, and vice versa.

However, the main challenge of AI-based quantization-aware CSI feedback lies in the non-differentiability of quantizer and de-quantizer, which bridge the float-type latent vector and the fixed-point codeword. There has been no study or report yet on vector-quantization-aware CSI feedback under the framework of separate training.

In contrary to quantization-unaware CSI feedback with scalar/vector quantization′ which has only two learnable functionalities (i.e., encoder and decoder), the quantization-aware CSI feedback with vector quantization is typically featured in joint learning of three functionalities (i.e., encoder, codebook, and decoder) at a single entity simultaneously, which is a type 1 training category. When it's extended to type-3 with separated training, the current experience/approach of type-1 to type-3 extension cannot be directly adopted, for there's a constraint the codebook for vector quantization has been pre-determined by network (NW) in a NW-first training manner, so encoder in UE-side needs to be learnt independently and meanwhile coherently with the pre-defined codebook. Therefore, detailed approach on training methodology including training procedures, required dataset, and feasible loss function may still need to be discussed.

Therefore, the present disclosure proposes a mechanism for separate training approach for CSI feedback based on the vector quantization. In this solution, the network device may determine a codebook of the network device and a first set of codeword indices by training a model based on the training dataset associated with CSI and provide the training dataset, the codebook of the network device and the first set of codeword indices to the terminal device. The terminal device may train the CSI feedback compression based on the received training dataset, the codebook of the network device and the first set of codeword indices.

In this way, a mechanism for separate training approach for CSI feedback based on the vector quantization is achieved and an enhanced system performance for the CSI feedback may be reached.

Example embodiments of the present disclosure will be described in detail below with reference to the accompanying drawings.

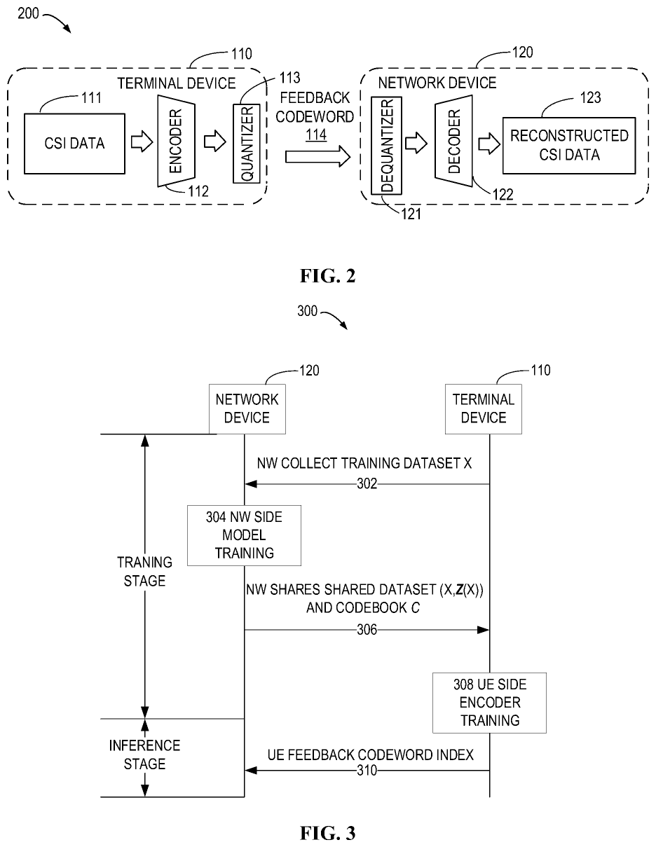

Reference is now made to FIG. 2, which shows an example of an overall structure for CSI compression and reconstruction according to some example embodiments of the present disclosure. The terminal device 110 side entity may include an encoder 112 compressing the original CSI data 111 into the latent feature vector and a quantizer 113 transforming the float-type latent vector into fixed-point codeword 114 for feedback. The network device 120 side entity may conversely include a dequantizer 121 transforming the fixed-point codeword 114 into the latent vector and a decoder 122 reconstructing the original CSI data 123.

Reference is now made to FIG. 3, which shows a signaling chart 300 for communication according to some example embodiments of the present disclosure. As shown in FIG. 3, the signaling chart 300 involves the terminal device 110 and the network device 120. For the purpose of discussion, reference is made to FIG. 1 to describe the signaling chart 300.

In the training phase, the network device 120 may collect (302) training dataset (for example, multiple stored history CSI data collected from the terminal device 110) and perform (304) a training process based on an AI/ML model for reconstructing the CSI feedback data. In this phase, a codebook of the network device, a decoder at the network device and a hypothetical encoder may be trained together based on a training dataset associated with CSI.

For the network device side training, the vector-quantization-aware training can be implemented by adopting the Vector Quantized Variational Autoencoder (VQ-VAE) scheme, which includes the following modules: an encoder may compress CSI data χ into the latent feature vector ξ; a segmentizer may divide a long latent vector ξ into multiple segments ξₖ; A vector quantizer may generate codeword index z by identifying the nearest codebook vector in codebook C given each segmented latent vector ξₖ; A vector dequantizer may generate each segmented codeword vₖ by referring to the codebook and codeword index z; A combiner may concatenate all codeword segments vₖ into a complete codeword v and A decoder may reconstruct the CSI data \hat{χ} by taking the codeword v as input.

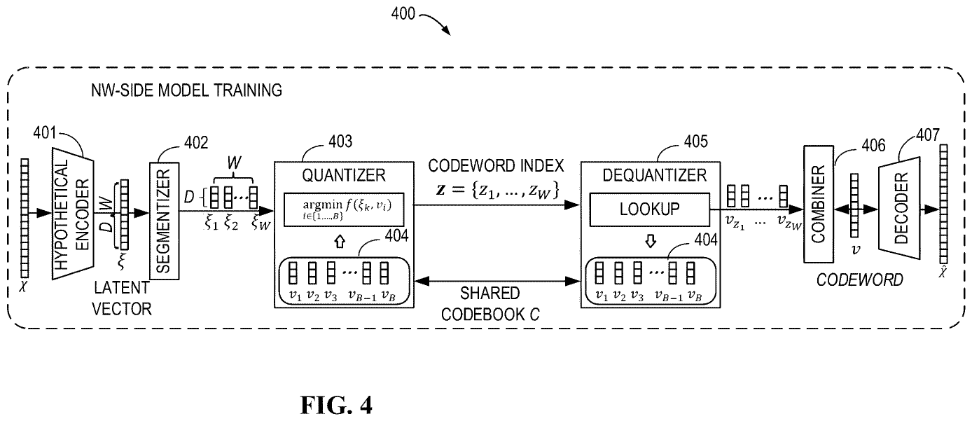

FIG. 4 shows an example of a model for network device side training according to some example embodiments of the present disclosure.

As shown, the model for network device side training 400 may comprise hypothetical encoder 401, a segmentizer 402, a quantizer 403, a codebook 404 of the network device 120 (designated as C), a dequantizer 405, a combiner 406 and a decoder 407.

In some embodiments, the training process of the network device 120 may be based on a vector-quantization-aware training.
during the training, the training dataset (designated as x) associated with CSI may be provided to the encoder 401. For example, the training dataset associated with CSI may be entire or a subset of the pre-stored CSI dataset.

The encoder 401 takes training dataset χ as input and outputs the compressed latent feature vector ξ. Most common deep network architectures (including fully connected (FC) layers, convolutional layers, transformer networks and long short-term memory (LSTM) networks, etc.) can be adopted as the encoder network.

In case the dimension of the latent vector is too large for codebook learning, ξ is divided into W segments ξₖ with a size of D by the segmentizer 402. All these segments are parallelly or sequentially fed into the quantizer 403 to produce the codeword index z.

Assuming the presence of a codebook 404 (designated as C) consisting of B codebook vectors with a dimension of D, the vector quantizer 403 first measures the distance between each codebook vector vᵢ and the given segment ξₖ. Then it outputs the index element zₖ with the minimum distance. This operation can be written as:

$${z}_{k} = {arg min}_{i ∈ \{ 1 , ... , B \}} f ( {ξ}_{k} , {v}_{i} ) , k ∈ \{ 1 , ... , W \} \qquad ( 1 )$$

wherein, f(⋅) represents the distance metric, which can be the Euclid distance, cosine similarity, etc. All index elements corresponding to W segments constitute the codeword index z=(z₁, . . . , z_{w}) for feedback.

The vector dequantizer 405 maintains the same codebook 404 (designated as C) with quantizer 403, so it can generate the segmented codeword {v_{z}_{₁}, v_{z}_{₂}, . . . , v_{z}_{_{w}}} by referring to C given the codeword index z.

The combiner 406 concatenates all segmented codeword {v_{z}_{₁}, v_{z}_{₂}, . . . , v_{z}_{_{w}}} to form the complete codeword v.

The decoder 407 takes v as input and reconstructs the training dataset. The decoder 407 can employ various deep network architectures like fully connected (FC) layers, convolutional layers, transformer networks and long short-term memory (LSTM) networks.

Based on whether the codebook 404 is updated along with the autoencoder during training as mentioned above, there are two options for the loss function using for the training.

For a learnable codebook, to train the encoder, codebook, and decoder in an end-to-end manner, the loss function can be written as:

$$Loss = R ( \hat{χ} , χ ) + {\sum }_{k = 1}^{W} f ( sg [ {ξ}_{k} ] , {v}_{{z}_{k}} ) + β \cdot {\sum }_{k = 1}^{W} f ( {ξ}_{k} , sg [ {v}_{{z}_{k}} ] ) \qquad ( 2 )$$

Wherein, R(⋅) denotes the reconstruction loss between the true CSI χ and the reconstructed CSI at the decoder output χ. The reconstruction loss can be measured in terms of normalized mean squared error (NMSE) or cosine similarity. As mentioned above, the segmented latent vector ξₖ is mapped to the closest codebook vector v_{z}_{ₖ}, which acts as the input to the decoder. Therefore, the second term, called quantization loss optimizes the codebook such that it becomes as close as possible to the encoder output. The encoder output is in this case, treated as a constant using the stop-gradient operator sg[⋅]. Specifically, the codebook can be updated by the dictionary learning algorithm with the L2-norm error. The last term is the commitment loss which in turn optimizes the encoder such that the output ξₖ commits to the codebook.

For a fixed codebook, as there is no need to update the codebook, the quantization loss for the learnable codebook, as described above, can be eliminated while preserving the other two losses. Therefore, the loss function can be written as follows:

$$Loss = R ( \hat{χ} , χ ) + β \cdot {\sum }_{k = 1}^{W} f ( {ξ}_{k} , sg [ {v}_{{z}_{k}} ] ) \qquad ( 3 )$$

In some other embodiments, the training process of the network device 120 may be based on a vector-quantization-unaware training. The training model as shown in FIG. 4 may also be adopted for the vector-quantization-unaware training. The difference between the vector-quantization-aware training and the vector-quantization-unaware training is the training of the autoencoder and the optimization of the vector quantizer are independent of each other.

In this training phase, the latent vector ξ is directly fed into the decoder 407 for CSI reconstruction, so the quantization error is not considered. After training the autoencoder, the vector quantizer 403 is optimized by referring to the characteristics of these latent vectors, which involves the following steps.

First, sufficient latent vectors generated by the encoder as a dataset V may be collected. Then a codebook 404 with D dimensions and B vectors may be initialized using a clustering algorithm such as k-means or random initialization. After that, each latent vector in V may be divided into W segments, and each segment may be assigned to its nearest codebook vector. The codebook may be updated by minimizing the discrepancy between the original latent vectors and their quantized representations.

Under the CSI feedback scenario, the discrepancy can be measured by the Euclidean distance or cosine similarity. There are various strategies to update the codebook, including the K-means clustering and the neural network-based method.

After NW-side model training, an appropriate shared dataset together with an associated codebook need to be shared to UE side for encoder training without knowledge about the NW-side model. Referring back to FIG. 3, the network device 120 may provide (306) the training dataset (designated as χ), the codebook C and the codeword index z(χ) associated with training dataset χ to the terminal device 110, which may also be referred to as a first set of codeword indices hereinafter. Hereinafter the training dataset (designated as χ) and the codeword index z(χ) associated with training dataset χ may also be referred to as shared dataset.

There are two benefits by providing such parameters to the terminal device 110. First, with a universal codebook C shared by both NW-side entity and UE-side entity, the codeword spaces derived from different UEs can be well aligned, which facilitates the reconstruction by the common NW-side decoder. Second, with a universal codebook C, the fixed-point codeword index z occupies much less resources than the float-type high-dimensional codeword v.

Then the terminal device 110 may perform (308) the training process based on the received training dataset (designated as χ), the codebook C and the codeword index z(χ) associated with training dataset χ to the terminal device 110.

For the terminal device side training, a dequantizer may reproduce the segmented codeword \acute{v}_{z}_{ₖ} by referring to the codeword index z and codebook C. A combiner to concatenate all segmented codeword into a complete codeword v. An encoder may compress the training dataset χ into the codeword \hat{v} as close as possible to the reference codeword v.

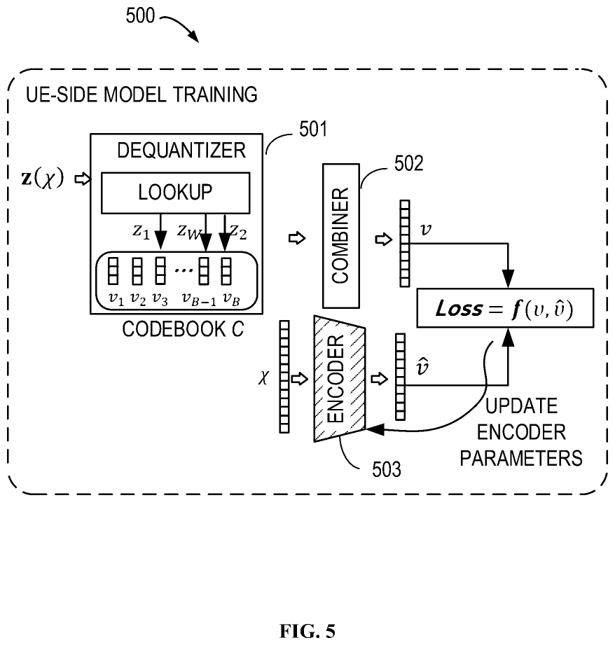

FIG. 5 shows an example of a model for terminal device side training according to some example embodiments of the present disclosure.

As shown, the model 500 for terminal device side training may comprise a dequantizer 501, a combiner 502 and the encoder 503.

The dequantizer 501 in terminal device side entity takes the codeword index z as input. Each element zₖ in z corresponds to a codebook vector, which is the segmented codeword v_{z}_{ₖ}. This dequantizer 501 can sequentially or parallelly map zₖ to v_{z}_{ₖ} by referring to the codebook C, and then, the combiner 502 concatenates all these segments into a complete codeword v as the reference for encoder training. In brief, the dequantizer 501 and combiner 502 only implement lookup and concatenating functionalities, so no extra information is needed.

The encoder 503 takes training dataset χ as input and outputs its associated codeword vector \hat{v}. Most common deep network architectures (including fully connected (FC) layers, convolutional layers, transformer networks and long short-term memory (LSTM) networks, etc.) can be adopted as the encoder network.

The encoder is trained to fit the encoder output \hat{v} to the reference codeword v by minimizing their difference in a supervised manner. The loss function can be any metric evaluating the distance between two vectors like mean square error (MSE) or generalized cosine similarity (GCS). The loss function adopted in our simulation is the MSE loss.

The embodiments described above explains how the network device side module and the terminal device side module are trained separately. In summary, the NW-side entity trains a hypothetical encoder, decoder, and codebook with a collection of prestored CSI dataset by adopting the VQ-VAE training structure. After training, the codebook C and all NN parameters of encoder and decoder are finalized in NW-side entity.

Then The NW-side entity generates and shares with UE a shared dataset together with the finalized codebook C. The shared dataset is constituted by the original training dataset X and corresponding codeword indices Z(X).

Given the pre-trained encoder and codebook, the training dataset χ is firstly compressed into a latent vector ξ, and then ξ is divided into W segments {ξ₁, ξ₂, . . . , ξ_{w}}. Given the codebook C constituted by B vectors {v₁, v₂, . . . , v_{B}}, W segments are mapped to their closest codebook vectors {v_{z}_{₁}, v_{z}_{₂}, . . . , v_{z}_{_{W}}} with each vector belonging to {v₁, v₂, . . . , v_{B}} as shown in FIG. 4. Meanwhile, the index vector z={z₁, z₂, . . . , z_{w}} indicating their locations within the codebook C is derived. Under the VQ-VAE framework, the flattened {v_{z}_{₁}, v_{z}_{₂}, . . . , v_{z}_{_{W}}} denoted by u rather than ξ is fed into the decoder. For brief description, the quantized latent vector ν(x) may be called as the codeword and index vector z(χ) as the codeword index given training dataset χ.

Rather than sharing with UE the codeword itself, the NW-side entity shares the finalized codebook C and the shared dataset (X, Z(X)) to the UE side for encoder training. (X, Z(X)) is the collection of massive (χ, z(χ)) pairs.

There are two major benefits from this design. First, with a universal codebook C shared by both NW-side entity and UE-side entity, the codeword spaces derived from different UEs can be well aligned, which facilitates the reconstruction by the common NW-side decoder. Second, with a universal codebook C, the fixed-point codeword index z occupies much less resources than the float-type high-dimensional codeword v.

Then the UE-side entity firstly reproduces the codeword v by referring to the codebook C given the codeword index z(χ). The encoder is then trained to compress the training dataset χ into the codeword \hat{v} by minimizing the difference between \hat{v} and the reference codeword v in a supervised manner. Here, the UE-side encoder can employ a completely different NN structure from the NW-side encoder. The loss function can be any suitable metric evaluating the distance between two vectors like mean square error (MSE) or generalized cosine similarity (GCS).

Based on the well-trained model 500 of terminal device side, as shown in FIG. 3, in the implementing phase (which may be called as inference stage), the NW-side entity and UE may share the same codebook C. The terminal device 110 may obtain actual CSI data and generate, based on the CSI data and a well-trained model at the terminal device 110 (for example, the model 500), a second set of codeword indices, and provide (310) the second set of codeword indices to the network device 120.

It is to be understood that the network device 120 may provide the the training dataset (designated as χ), the codebook C and the codeword index z(χ) associated with training dataset χ to multiple terminal devices. The multiple terminal device 110 may train itself based on the received training parameters.

Based on the received second set of codeword indices and a well-trained model at the network device 120 (for example, the model 400), the network device 120 may reconstruct the CSI data obtained at the terminal device.

A simulation based on the solution of the present disclosure may be discussed as below. The configurations for shared dataset generation are given in the following.

TABLE 1
Dataset configurations

| Carrier Frequency | 3.5 | GHz |
|---|---|---|
| Bandwidth | 10 | MHz |
| Subcarrier Spacing | 15 | KHz |
| RB Number | 48 | |
| Sub-band Number | 12 | |
| Antenna | 32 Tx ports: (4, 4, 2, 1, 1, 1, 1), | |
| Configuration | (dH, dV) = (0.5, 0.5)λ, directional | |
| | 4 Rx ports: (1, 2, 2, 1, 1, 1, 1), | |
| | (dH, dV) = (0.5, 0.5)λ, directional | |
| Channel Model | CDL-C | |
| Delay Spread | 300 | ns |
| UE Speed | 3 | km/h |

| | |
|---|---|
| Rank | 1 |
| Channel Estimation | ideal |

In this simulation, there are 100000 eigenvector samples as CSI data for training and validation. Thereinto, 80000 samples are used for training and 20000 samples are used for validation. Each sample includes N=728 real numbers, which corresponds to a large eigenvector concatenated by 12 sub-bands as:

$$χ = [ {x}_{1} , {x}_{2} , … , {x}_{12} ] \qquad ( 4 )$$

wherein xₖ (1≤k≤12) is the eigenvector for the k-th sub-band channel.

Each xx has been processed as the following format:

$${x}_{k} = [ Re \{ {x}_{k , 1} \} , Im \{ {x}_{k , 1} \} , Re \{ {x}_{k , 2} \} , Im \{ {x}_{k , 2} \} , ... , Re \{ {x}_{k , 32} \} , Im \{ {x}_{k , 32} \} ] \qquad ( 5 )$$

wherein Re{.} and Im{.} are the real and imaginary parts.

In this simulation, a SGCS is used between the original CSI data and the reconstructed CSI data as the performance metric.

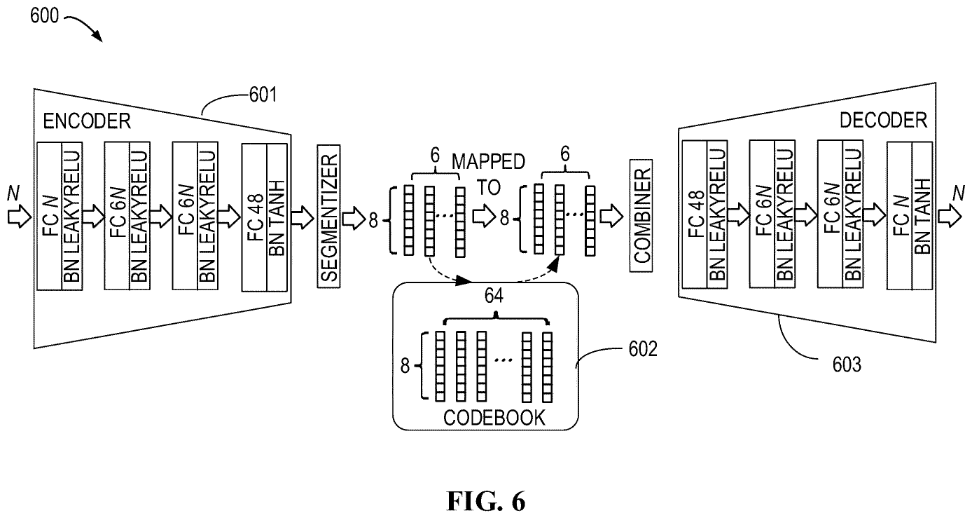

Firstly, the superiority of the proposed NW-first vector-quantization-aware separate training scheme is proved. The detailed model structure of the proposed scheme is shown in FIG. 6, which may comprise an encoder 601 and a decoder 602. To achieve a fair comparison, the number of overhead bits after quantization is set to 36 for all compared schemes. For the vector-quantization-based scheme, as shown in FIG. 6, the number of codebook vectors B of the codebook 603 and the number of segments W is 64 and 6 respectively, so the number of overhead bits is

$$W \cdot {log}_{2}^{B} = 6 \cdot {log}_{2}^{64} = 36.$$

For the scalar-quantization-aware scheme, the dimension of the output (i.e., latent vector) is set as 12 and each latent vector element is quantized to 8 levels (i.e., 3 bits), so the number of overhead bits is also

$$12 \cdot {log}_{2}^{8} = 36.$$

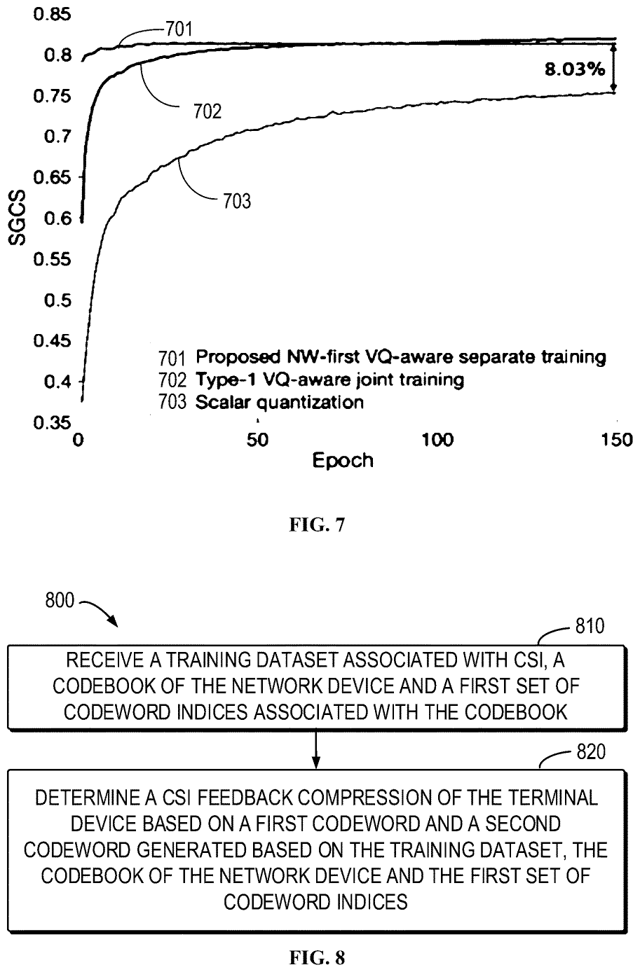

The simulation result shown in FIG. 7 presents the convergence performance of different schemes in terms of the SGCS. There are two observations from this simulation result: (1) the NW-first VQ-aware separate training scheme (curve 701) can achieve an approximating performance with the type 1 joint training scheme (less than 0.8% degradation); (2) the vector-quantization-based training scheme (curves 702 and 703) can achieve significant performance gain over the scalar-quantization-based scheme (over 8% improvements).

The simulation results demonstrate the advantage of the proposed NW-first vector-quantization-aware separate training approach, which includes the proposed approach for CSI feedback enhancement can achieve a comparable performance with the type 1 joint training approach; The proposed approach significantly outperforms the scalar-quantization-based scheme; and there is no performance degradation with UE-side NN structure not aligned with NW-side NN structure.

The proposed solution of the present disclosure proposes a mechanism of separate training for CSI feedback. This present disclosure considers the separate training framework for vector-quantization-aware CSI feedback enhancement, which not only exploits the performance advantage of vector-quantization-aware training, but also avoids the exposure of proprietary NN models in the real deployment, i.e., to enable quantization-aware CSI feedback with vector quantization under the framework of (type-3) sperate training.

Furthermore, with such universal codebook learnt and provided by NW, different UEs can be well constrained in learning its individual encoder under a common quantized feature space, which contributes to good reconstruction by a common NW-side decoder. The learnt codebook and decoder in NW are universal and this approach is friendly to system scalability with new arrival of UEs, i.e., NW-side decoder can accommodate new UEs without retraining.

Last but not the least, with a universal codebook, the codeword index z(χ) in the shared dataset is an integer-type index vector, which occupies much less resources than the codeword v itself and therefore the dataset distribution efficiency may be enhanced.

FIG. 8 shows a flowchart of an example method 800 of separate training approach for CSI feedback according to some example embodiments of the present disclosure. The method 800 may be implemented at the terminal device 110 as shown in FIG. 1. For the purpose of discussion, the method 800 will be described with reference to FIG. 1.

At 810, the terminal device 110 receives from a network device, a training dataset associated with CSI, a codebook of the network device and a first set of codeword indices associated with the codebook.

At 820, the terminal device 110 determine a CSI feedback compression of the terminal device based on a first codeword and a second codeword generated based on the training dataset, the codebook of the network device and the first set of codeword indices.

In some example embodiments, the terminal device may generate the first codeword by selecting vectors corresponding to the set of codeword indices from the codebook; generate the second codeword by compressing the training dataset at an encoder of the terminal device for performing the CSI feedback compression; and train the encoder at the terminal device by using a loss function to minimize a difference between the second codeword and the first codeword.

In some example embodiments, the loss function is based on a mean square error or a generalized cosine similarity.

In some example embodiments, the terminal device may obtain a CSI data; generate a second set of codeword indices associated with the codebook from the CSI data based on the determined CSI feedback compression; and transmit the second set of codeword indices to the network device.

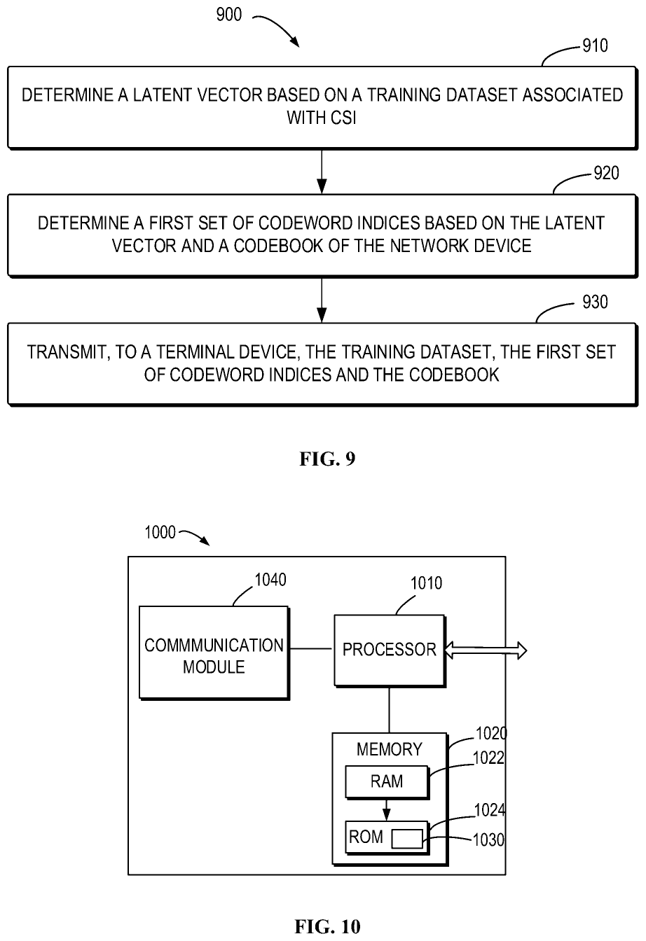

FIG. 9 shows a flowchart of an example method 900 of separate training approach for CSI feedback according to some example embodiments of the present disclosure. The method 900 may be implemented at the network device 120 as shown in FIG. 1. For the purpose of discussion, the method 900 will be described with reference to FIG. 1.

At 910, the network device 120 determines a latent vector based on a training dataset associated with CSI.

At 920, the network device 120 determines a first set of codeword indices based on the latent vector and a codebook of the network device.

At 930, the network device 120 transmits, to a terminal device, the training dataset, the first set of codeword indices and the codebook.

In some example embodiments, the network device 120 may generate a set of segmented latent vectors from the latent vector; determine, from the codebook, a plurality of segmented codewords each corresponding to a segmented latent vector; and determine the first set of codeword indices based on the plurality of segmented codewords.

In some example embodiments, the network device 120 may receive, from the terminal device, a second set of codeword indices associated with the codebook, wherein the second set of codeword indices are generated by performing a CSI feedback compression on a CSI data at the terminal device; and reconstruct the CSI data associated with CSI based on the received second set of codeword indices and the codebook of the network device.

In some example embodiments, the network device 120 may generate a codeword based on the received second set of codeword indices and the codebook of the network device; and reconstruct the CSI data associated with CSI by decoding the generated codeword.

In some example embodiments, an apparatus capable of performing the method 800 (for example, implemented at the terminal device 110) may include means for performing the respective steps of the method 800. The means may be implemented in any suitable form. For example, the means may be implemented in a circuitry or software module.

In some example embodiments, the apparatus comprises means for receiving, from a network device, a training dataset associated with CSI, a codebook of the network device and a first set of codeword indices associated with the codebook; and means for determining a CSI feedback compression of the apparatus based on a first codeword and a second codeword generated based on the training dataset, the codebook of the network device and the first set of codeword indices.

In some example embodiments, the apparatus comprises means for generating the first codeword by selecting vectors corresponding to the set of codeword indices from the codebook; means for generating the second codeword by compressing the training dataset at an encoder of the apparatus for performing the CSI feedback compression; and means for training the encoder at the apparatus by using a loss function to minimize a difference between the second codeword and the first codeword.

In some example embodiments, the loss function is based on a mean square error or a generalized cosine similarity.

In some example embodiments, the apparatus comprises means for obtaining a CSI data; generate a second set of codeword indices associated with the codebook from the CSI data based on the determined CSI feedback compression; and means for transmitting the second set of codeword indices to the network device.

In some example embodiments, an apparatus capable of performing the method 900 (for example, implemented at the network device 120) may include means for performing the respective steps of the method 900. The means may be implemented in any suitable form. For example, the means may be implemented in a circuitry or software module.

In some example embodiments, the apparatus comprises means for determining a latent vector based on a training dataset associated with CSI; means for determining a first set of codeword indices based on the latent vector and a codebook of the apparatus; and means for transmitting, to a terminal device, the training dataset, the first set of codeword indices and the codebook.

In some example embodiments, the apparatus comprises means for generating a set of segmented latent vectors from the latent vector; means for determining, from the codebook, a plurality of segmented codewords each corresponding to a segmented latent vector; and means for determining the first set of codeword indices based on the plurality of segmented codewords.

In some example embodiments, the apparatus comprises means for receiving, from the terminal device, a second set of codeword indices associated with the codebook, wherein the second set of codeword indices are generated by performing a CSI feedback compression on a CSI data at the terminal device; and means for reconstructing the CSI data associated with CSI based on the received second set of codeword indices and the codebook of the apparatus.

In some example embodiments, the apparatus comprises means for generating a codeword based on the received second set of codeword indices and the codebook of the apparatus; and means for reconstructing the CSI data associated with CSI by decoding the generated codeword.

FIG. 10 is a simplified block diagram of a device 1000 that is suitable for implementing example embodiments of the present disclosure. The device 1000 may be provided to implement a communication device, for example, the terminal device 110 or the network device 120 as shown in FIG. 1. As shown, the device 1000 includes one or more processors 1010, one or more memories 1020 coupled to the processor 1010, and one or more communication modules 1040 coupled to the processor 1010.

The communication module 1040 is for bidirectional communications. The communication module 1040 has one or more communication interfaces to facilitate communication with one or more other modules or devices. The communication interfaces may represent any interface that is necessary for communication with other network elements. In some example embodiments, the communication module 1040 may include at least one antenna.

The processor 1010 may be of any type suitable to the local technical network and may include one or more of the following: general purpose computers, special purpose computers, microprocessors, digital signal processors (DSPs) and processors based on multicore processor architecture, as non-limiting examples. The device 1000 may have multiple processors, such as an application specific integrated circuit chip that is slaved in time to a clock which synchronizes the main processor.

The memory 1020 may include one or more non-volatile memories and one or more volatile memories. Examples of the non-volatile memories include, but are not limited to, a Read Only Memory (ROM) 1024, an electrically programmable read only memory (EPROM), a flash memory, a hard disk, a compact disc (CD), a digital video disk (DVD), an optical disk, a laser disk, and other magnetic storage and/or optical storage. Examples of the volatile memories include, but are not limited to, a random access memory (RAM) 1022 and other volatile memories that will not last in the power-down duration.

A computer program 1030 includes computer executable instructions that are executed by the associated processor 1010. The instructions of the program 1030 may include instructions for performing operations/acts of some example embodiments of the present disclosure. The program 1030 may be stored in the memory, e.g., the ROM 1024. The processor 1010 may perform any suitable actions and processing by loading the program 1030 into the RAM 1022.

The example embodiments of the present disclosure may be implemented by means of the program 1030 so that the device 1000 may perform any process of the disclosure as discussed with reference to FIG. 2 to FIG. 9. The example embodiments of the present disclosure may also be implemented by hardware or by a combination of software and hardware.

In some example embodiments, the program 1030 may be tangibly contained in a computer readable medium which may be included in the device 1000 (such as in the memory 1020) or other storage devices that are accessible by the device 1000. The device 1000 may load the program 1030 from the computer readable medium to the RAM 1022 for execution. In some example embodiments, the computer readable medium may include any types of non-transitory storage medium, such as ROM, EPROM, a flash memory, a hard disk, CD, DVD, and the like. The term “non-transitory,” as used herein, is a limitation of the medium itself (i.e., tangible, not a signal) as opposed to a limitation on data storage persistency (e.g., RAM vs. ROM).

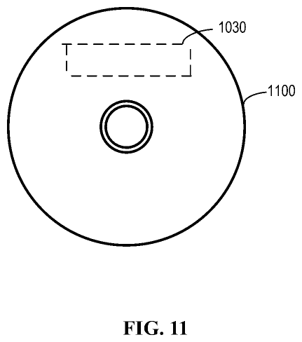

FIG. 11 shows an example of the computer readable medium 1100 which may be in form of CD, DVD or other optical storage disk. The computer readable medium 1100 has the program 1030 stored thereon.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representations, it is to be understood that the block, apparatus, system, technique or method described herein may be implemented in, as non-limiting examples, hardware, software, firmware, special purpose circuits or logic, general purpose hardware or controller or other computing devices, or some combination thereof.

Some example embodiments of the present disclosure also provide at least one computer program product tangibly stored on a computer readable medium, such as a non-transitory computer readable medium. The computer program product includes computer-executable instructions, such as those included in program modules, being executed in a device on a target physical or virtual processor, to carry out any of the methods as described above. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. The program code may be provided to a processor or controller of a general purpose computer, special purpose computer, or other programmable data processing apparatus, such that the program code, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

In the context of the present disclosure, the computer program code or related data may be carried by any suitable carrier to enable the device, apparatus or processor to perform various processes and operations as described above. Examples of the carrier include a signal, computer readable medium, and the like.

The computer readable medium may be a computer readable signal medium or a computer readable storage medium. A computer readable medium may include but not limited to an electronic, magnetic, optical, electromagnetic, infrared, or semiconductor system, apparatus, or device, or any suitable combination of the foregoing. More specific examples of the computer readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Unless explicitly stated, certain features that are described in the context of separate embodiments may also be implemented in combination in a single embodiment. Conversely, unless explicitly stated, various features that are described in the context of a single embodiment may also be implemented in a plurality of embodiments separately or in any suitable sub-combination.

Although the present disclosure has been described in languages specific to structural features and/or methodological acts, it is to be understood that the present disclosure defined in the appended claims is not necessarily limited to the specific features or acts described above. Rather, the specific features and acts described above are disclosed as example forms of implementing the claims.

What is claimed is:

1. An apparatus comprising:
at least one processor; and
at least one memory storing instructions that, when executed by the at least one processor, cause the apparatus at least to:
receive, from a network device, a training dataset associated with channel state information, CSI, a codebook of the network device and a first set of codeword indices associated with the codebook; and
determine a CSI feedback compression of the apparatus based on a first codeword and a second codeword generated based on the training dataset, the codebook of the network device and the first set of codeword indices.

2. The apparatus of claim 1, wherein the apparatus is further caused to:
generate the first codeword by selecting vectors corresponding to the set of codeword indices from the codebook;
generate the second codeword by compressing the training dataset at an encoder of the apparatus for performing the CSI feedback compression; and
train the encoder at the apparatus by using a loss function to minimize a difference between the second codeword and the first codeword.

3. The apparatus of claim 2, wherein the loss function is based on a mean square error or a generalized cosine similarity.

4. The apparatus of claim 1, wherein the apparatus is further caused to:
obtain CSI data;
generate a second set of codeword indices associated with the codebook from the CSI data based on the determined CSI feedback compression; and
transmit the second set of codeword indices to the network device.

5. An apparatus comprising:
at least one processor; and
at least one memory storing instructions that, when executed by the at least one processor, cause the apparatus at least to:
determine a latent vector based on a training dataset associated with channel state information, CSI;
determine a first set of codeword indices based on the latent vector and a codebook of the apparatus; and
transmit, to a terminal device, the training dataset, the first set of codeword indices and the codebook.

6. The apparatus of claim 5, wherein the apparatus is further caused to:
generate a set of segmented latent vectors from the latent vector;
determine, from the codebook, a plurality of segmented codewords each corresponding to a segmented latent vector; and
determine the first set of codeword indices based on the plurality of segmented codewords.

7. The apparatus of claim 5, wherein the apparatus is further caused to:
receive, from the terminal device, a second set of codeword indices associated with the codebook, wherein the second set of codeword indices are generated by performing a CSI feedback compression on CSI data at the terminal device; and
reconstruct the CSI data associated with CSI based on the received second set of codeword indices and the codebook of the apparatus.

8. The apparatus of claim 7, wherein the apparatus is further caused to:
generate a codeword based on the received second set of codeword indices and the codebook of the apparatus; and
reconstruct the CSI data associated with CSI by decoding the generated codeword.

9. A method comprising:
receiving, at a terminal device and from a network device, a training dataset associated with channel state information, CSI, a codebook of the network device and a first set of codeword indices associated with the codebook; and
determining a CSI feedback compression of the terminal device based on a first codeword and a second codeword generated based on the training dataset, the codebook of the network device and the first set of codeword indices.

10. A method comprising:
determining, at a network device, a latent vector based on a training dataset associated with channel state information, CSI;
determining a first set of codeword indices based on the latent vector and a codebook of the network device; and
transmitting, to a terminal device, the training dataset, the first set of codeword indices and the codebook.

11. An apparatus comprising:
means for receiving from a network device, a training dataset associated with channel state information, CSI, a codebook of the network device and a first set of codeword indices associated with the codebook; and
means for determining a CSI feedback compression of the apparatus based on a first codeword and a second codeword generated based on the training dataset, the codebook of the network device and the first set of codeword indices.

12. An apparatus comprising:
means for determining a latent vector based on a training dataset associated with channel state information, CSI;
means for determining a first set of codeword indices based on the latent vector and a codebook of the apparatus; and
means for transmitting, to a terminal device, the training dataset, the first set of codeword indices and the codebook.

13. A computer readable medium comprising instructions which, when executed by an apparatus, cause the apparatus to perform at least the method of claim 9 or the method of claim 10.
